(19) United States
(12) Patent Application Publication
(10) Pub. No.: US 2006/0102918 A1
(43) Pub. Date: May 18, 2006

(54) Package Structure of a Surface Mount Device Light Emitting Diode

(76) Inventors: Wen-Lung Su, Nan-Tou Hsien (TW); Tse-Min Mao, Taipei City (TW)

Correspondence Address: NORTH AMERICA INTELLECTUAL PROPERTY CORPORATION, P.O. BOX 506, MERRIFIELD, VA, 22116, US

(21) Appl. No.: 10/907,379

(22) Filed: Mar. 31, 2005

(30) Foreign Application Priority Data
Nov. 16, 2004 (TW) 093135154

(51) Int. Cl. H01L 33/00

(52) U.S. Cl. 257/99

(57) ABSTRACT

A surface mount device (SMD) light emitting diode (LED) package structure is disclosed. The structure includes a cup-structure substrate, a lead frame, an LED chip, a set of conducting wires, and a transparent or semi-transparent seal. The inner or outer surface of the cup-structure substrate includes a plurality of indentations that may be different in number, size, depth, and shape. The indentations are formed by injection molding techniques or pressure stamping. By filling the indentations with the transparent or semi-transparent seal, the SMD LED package structure is able to enhance the attachment between the cup-structure substrate and the seal and thereby effectively prevent any separation from the two bodies as a result of an external force.

### BACKGROUND OF INVENTION

1. Field of the Invention

The present invention relates to a surface mount device (SMD) light emitting diode (LED) package structure, and more particularly, to a package structure including a plurality of indentations formed in the inner or outer surface of the package structure substrate by injection molding or stamping.

2. Description of the Prior Art

Since a light-emitting diode (LED) has the advantages of a long lifetime, a small size, and a low consumption of electric power, the LED is widely applied in pilot lamps or light sources of various household appliances and instruments. Additionally, the LED is developed toward full colors and high brightness, so that the LED is further applied in large-sized display signboards and traffic lights, and it may substitute for tungsten lamps and mercury lamps in the future.

Please refer to FIG. 1 and FIG. 2. FIG. 1 is a top view diagram showing a conventional package structure of a surface mount device (SMD) light emitting diode and FIG. 2 is a cross section view showing the package structure of FIG. 1 in the 1-1′ direction. As shown in FIG. 1 and FIG. 2, an SMD LED package structure 10 comprises a cup-structure substrate 12, a lead frame 14, an LED chip 16, conducting wires 18 and 20, and a sealant 22. As a semiconductor device comprising a positive electrode and a negative electrode (not shown), the LED chip 16 is illuminated by receiving power from an external voltage source and connected to the lead frame 14 by the conducting wires 18 and 20. Situated in the cup-structure substrate 12, the lead frame 14 is extended to the outer surface of the cup-structure substrate 12, which will be utilized as a contact point in the mounting process performed in a later stage.

When the SMD LED package structure 10 is fabricated according to the conventional method, an epoxy, silicon, a transparent sealing compound, or a semi-transparent compound is utilized to fill into the cup-structure substrate and cover the LED chip 16 and the conducting wires 18 and 20. After the sealing compound is solidified, a sealant 22 is formed for protecting the LED chip 16 and the conducting wires 18 and 20. However, due to the poor adhesion between the cup-structure substrate 12 and the sealant 22, an external force will easily cause a detachment of the sealant 22 from the substrate 12 and greatly influence the fabrication efficiency of the SMD LED package structure 10.

### SUMMARY OF INVENTION

It is therefore an objective of the present invention to provide a surface mount device light emitting diode package structure for solving the above-mentioned problems.

According to the present invention, a light emitting diode (LED) package structure comprises: a cup-structure substrate, wherein the inner surface of the cup-structure substrate includes a plurality of first indentations that are different in shape, size, and depth; a lead frame, disposed in the cup-structure substrate and extend to the external surface of the substrate; a light emitting diode chip, disposed on top of the cup-structure substrate, comprising a positive electrode and a negative electrode; at least one conducting wire connecting to the light emitting diode chip and the lead frame; and a sealant covering the light emitting diode chip.

By forming a plurality of indentations that are different in shape, size, and depth in the inner or outer wall of the substrate, the SMD LED package structure of the present invention is able to enhance the overall package structure and prevent the detachment of sealant from the substrate as a result of an external force.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a top view diagram showing the package structure of a surface mount device light emitting diode according to the prior art.

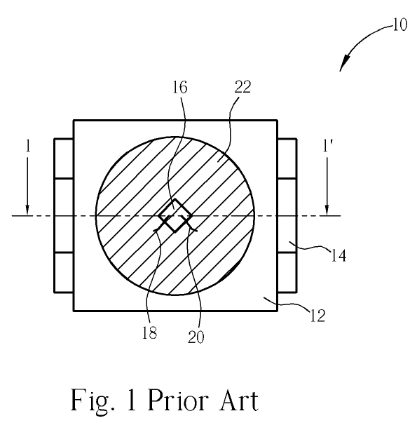

FIG. 2 is a cross section view showing the package structure of FIG. 1 in the 1-1′ direction.

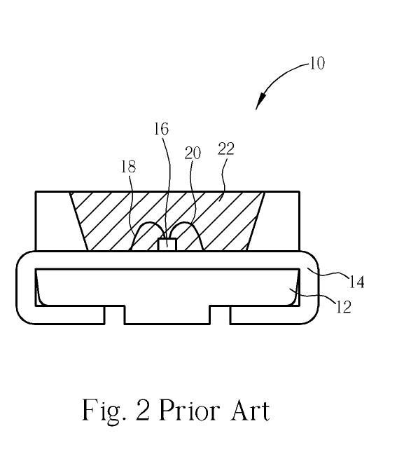

FIG. 3 is a perspective diagram showing a detachment of injected sealant caused by an external force.

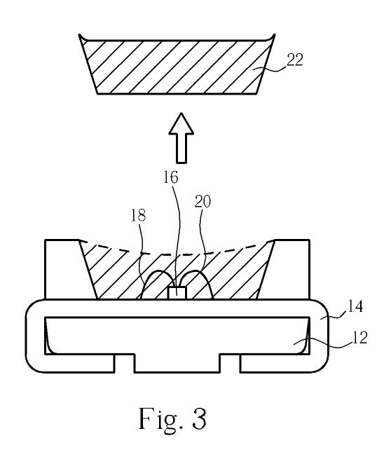

FIG. 4 is a top view diagram showing the package structure of a surface mount device light emitting diode according to the present invention.

FIG. 5 is a cross section view showing the package structure of FIG. 4 in the 4-4′ direction.

FIG. 6 is a cross section view showing the package structure of a surface mount device light emitting diode according to the second embodiment of the present invention.

FIG. 7 is a cross section view showing the package structure of a surface mount device light emitting diode according to the third embodiment of the present invention.

FIG. 8 is a cross section view showing the package structure of a surface mount device light emitting diode according to the fourth embodiment of the present invention.

FIG. 9 is a cross section view showing the package structure of a surface mount device light emitting diode according to the fifth embodiment of the present invention.

### DETAILED DESCRIPTION

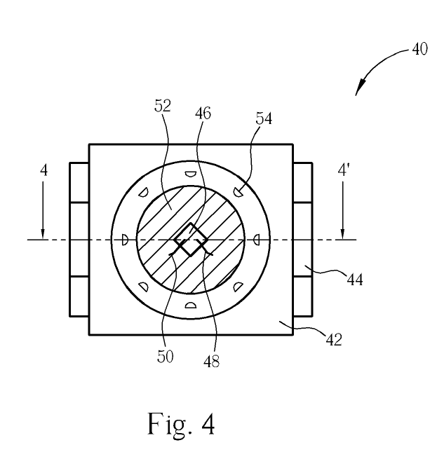

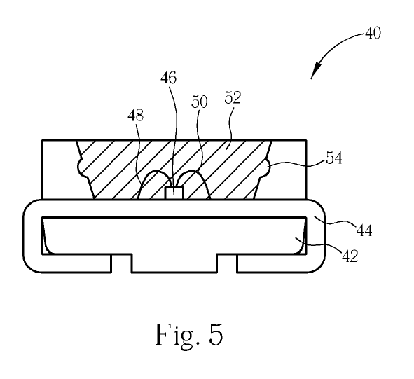

Please refer to FIG. 4 and FIG. 5. FIG. 4 is a top view diagram showing the package structure of a surface mount device light emitting diode according to the present invention where as FIG. 5 is a cross section view showing the package structure of FIG. 4 in the 4-4′ direction. As shown in FIG. 4 and FIG. 5, an SMD LED package structure 40 comprises a cup-structure substrate 42, a lead frame 44, an LED chip 46, conducing wires 48 and 50, and a sealant 52.

Similar to the conventional LED package structure, the LED chip 46, comprising a positive electrode and a negative electrode, is also electrically connected to the lead frame 44 through the conducting wires 48 and 50. Situated in the cup-structure substrate 42, the lead frame 44, which also serves as a contact point during the surface mounting process in a later stage, is extended to the outer surface of the substrate. The sealant 52, comprised of epoxy or silicon, is used for protecting and fixing the LED chip 46 and the conducting wire 48 in place. According to the preferred embodiment of the present invention, a plurality of semicircular indentations 54 is formed in the inner surface of the cup-structure substrate 42 and as shown in FIG. 4 and FIG. 5, the indentations 54 are formed in the central region of the cup-structure substrate. The indentations 54 can be formed by injection molding, hot pressing, or stamping and the number, shape, and location of the indentations can also be adjusted accordingly.

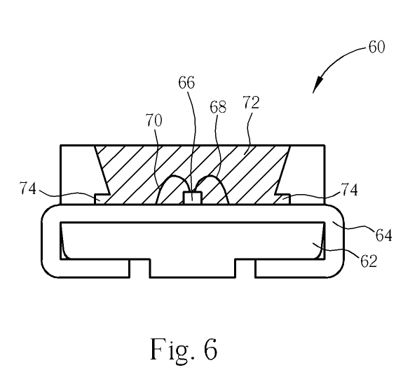

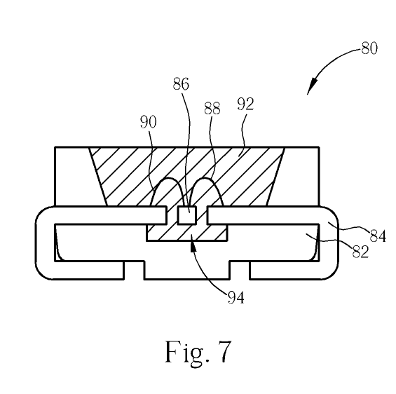

Please refer to FIG. 6 and FIG. 7. FIG. 6 and FIG. 7 are cross section views showing the package structure of a surface mount device light emitting diode according to the second and third embodiment of the present invention. As shown in FIG. 6, an SMD LED package structure 60 comprises a cup-structure substrate 62, a lead frame 64, an LED chip 66, conducting wires 68 and 70, and a sealant 72. In contrast to the preferred embodiment, a plurality of indentations 74 is formed in the bottom of the inner surface of the cup-structure substrate 62. The indentations 74 can be formed by injection molding, hot pressing, or stamping and the number, shape, and location of the indentations 74 can also be adjusted accordingly.

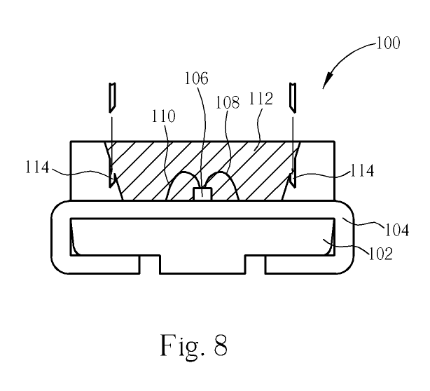

As shown in FIG. 7, an SMD LED package structure 80 comprises a cup-structure substrate 82, a lead frame 84, an LED chip 86, conducting wires 88 and 90, and a sealant 92. In this embodiment, a plurality of indentations 94 is formed in the central bottom of the cup-structure substrate 82. The indentations 94 are formed by internal injection molding and the number, shape, and location of the indentations 94 can also be adjusted accordingly. Please refer to FIG. 8. FIG. 8 is a cross section view showing the package structure of a surface mount device light emitting diode according to the fourth embodiment of the present invention. As shown in FIG. 8, an SMD LED package structure 100 comprises a cup-structure substrate 102, a lead frame 104, an LED chip 106, conducting wires 108 and 110, and a sealant 112. In contrast to the first embodiment, a plurality of indentations 114 located in inner surface of the cup-structure substrate 112 is formed by the punching of stamping equipments. In addition, the number, shape, and location of the indentations 114 can be adjusted according to actual requirements of the finished product.

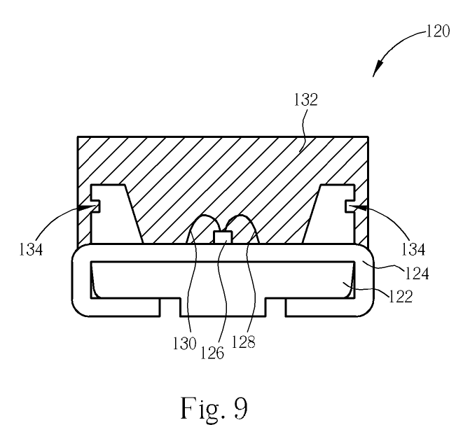

Please refer to FIG. 9. FIG. 9 is a cross section view showing the package structure of a surface mount device light emitting diode according to the fifth embodiment of the present invention. As shown in FIG. 9, an SMD LED package structure 120 comprises a cup-structure substrate 122, a lead frame 124, an LED chip 126, conducting wires 128 and 130, and a sealant 132. According to the present embodiment, a plurality of indentations 134 is formed in the surface of the outer wall of the cup-structure substrate 122 by injection molding or stamping processes. During the sealing process, the sealant 132 will first cover the LED chip 126 and the conducting wires 128 and 130, overflow from the cup-structure substrate 122, and completely cover the indentations 134 formed in the outer wall surface. In the same way, the number, shape, and location of the indentations 134 can be adjusted according to the requirements of the finished product.

In contrast to the conventional SMD LED, the structure disclosed by the present invention characterizes a plurality of indentation formations that are different in number, size, and shape in the inner or outer wall of the cup-structure substrate. Essentially, the indentations are able to increase the adhesion ability between the cup-structure substrate and the sealant, thereby preventing the detachment of sealant from the substrate and increasing the overall fabrication efficiency. Additionally, the present invention can be applied in the package structure of numerous products including LED lamps, LED frames, and LED dot matrix.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting diode (LED) package structure comprising:
a cup-structure substrate, wherein the inner surface of the cup-structure substrate includes a plurality of first indentations that are different in shape, size, and depth;
a lead frame, disposed in the cup-structure substrate and extend to the external surface of the substrate;
a light emitting diode chip, disposed on top of the cup-structure substrate, comprising a positive electrode and a negative electrode;
at least one conducting wire connecting to the light emitting diode chip and the lead frame; and
a sealant covering the light emitting diode chip.

2. The light emitting diode structure of claim 1, wherein the first indentations are formed in the inner surface of the cup-structure substrate by injection molding.

3. The light emitting diode structure of claim 1, wherein the first indentations are formed in the inner surface of the cup-structure substrate by stamping tools.

4. The light emitting diode structure of claim 1, wherein the sealant is filled into the first indentations that are located in the inner surface of the cup-structure substrate.

5. The light emitting diode structure of claim 1, wherein the sealant is an epoxy or a sealing material used in packaging processes.

6. The light emitting diode structure of claim 1, wherein the sealant is a transparent or semi-transparent sealant.

7. The light emitting diode structure of claim 1, wherein the outer surface of the cup-structure substrate includes a plurality of second indentations that are different in shape, size, and depth.

8. The light emitting diode structure of claim 1, wherein the light emitting diode is a surface mount device light emitting diode.

9. A surface mount device (SMD) light emitting diode package structure comprising:
a cup-structure substrate, wherein the outer surface of the cup-structure substrate includes a plurality of first indentations that are different in shape, size, and depth;
a lead frame, disposed in the cup-structure substrate and extend to the external surface of the substrate;
a light emitting diode chip, disposed on top of the cup-structure substrate, comprising a positive electrode and a negative electrode;
at least one conducting wire connecting to the light emitting diode chip and the lead frame; and
a sealant covering the light emitting diode chip.

10. The surface mount device light emitting diode package structure of claim 9, wherein the first indentations are formed in the outer surface of the cup-structure substrate by injection molding.

11. The surface mount device light emitting diode package structure of claim 9, wherein the first indentations are formed in the outer surface of the cup-structure substrate by stamping tools.

12. The surface mount device light emitting diode package structure of claim 9, wherein the sealant is filled into the first indentations that are located in the outer surface of the cup-structure substrate.

13. The surface mount device light emitting diode package structure of claim 9, wherein the sealant is an epoxy or a sealing material used in packaging processes.

14. The surface mount device light emitting diode package structure of claim 9, wherein the sealant is a transparent or semi-transparent sealant.

15. The surface mount device light emitting diode package structure of claim 9, wherein the inner surface of the cup-structure substrate includes a plurality of second indentations that are different in shape, size, and depth.
